(19) United States
(12) Patent Application Publication
(10) Pub. No.: US 2026/0182266 A1
(43) Pub. Date: Jun. 25, 2026

(54) PULSED CHEMICAL VAPOR DEPOSITION WITH PROGRAMMABLE LOGIC CONTROL

(71) Applicant: Applied Materials, Inc., Santa Clara, CA (US)

(72) Inventors: Yang ZHOU, San Jose, CA (US); Zhiyuan WU, San Jose, CA (US); Hyman W. H. LAM, San Jose, CA (US); Kevin KASHEFI, Dublin, CA (US)

(21) Appl. No.: 18/988,682

(22) Filed: Dec. 19, 2024

(51) Int. Cl. H01L 21/02; C23C 16/455; H01L 21/768; H01L 23/532

(52) U.S. Cl. CPC H10P 14/6339; C23C 16/45523; H10P 14/69396; H10W 20/033; H10W 20/057; H10W 20/076; H10W 20/425

(57) ABSTRACT

Embodiments described herein generally relate to semiconductor device fabrication. More specifically, embodiments of the present disclosure relate to methods of forming a conformal liner on inner sidewalls of a via and/or a trench structure. The present disclosure generally provides a method of depositing a liner layer in a semiconductor structure. The method includes forming a passivation layer, forming a barrier layer, forming the liner layer, and filing the via and the trench with a conductive material. Forming the liner layer includes holding a precursor gas in a gas line upstream from a processing chamber behind a closed programmable logic control (PLC) valve, wherein the precursor gas is held behind the closed PLC valve for a PLC valve close period and releasing the precursor gas into the processing chamber by opening the PLC valve, wherein the precursor gas is released into the processing chamber for a PLC valve open period.

### BACKGROUND

### Field

Embodiments described herein generally relate to semiconductor device fabrication. More specifically, embodiments of the present disclosure relate to methods of forming a conformal liner on inner sidewalls of a via and/or a trench structure.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., dynamic random access memory (DRAM)) and logic devices, including both planar and three-dimensional structures. Examples of three-dimensional structures are fin field-effect transistor (finFET) and metal oxide silicon field-effect transistor (MOSFET) devices.

In interconnects used in silicon integrated circuits (ICs), barrier layers are typically used to surround interconnects (e.g., copper interconnects) to prevent diffusion and other adverse interactions in surrounding materials. At a small device dimension, such as via bottom critical dimension (CD) of less than 12 nm, typical barrier layers and liner layers on sidewalls of the via can be thicker than 3 nm, leaving a small volume within the via to fill with copper and thus leading to a high via resistance. When depositing a liner layer over a barrier layer that is less metallic, nucleation delay, and liner layer degradation may occur within the via.

Therefore, there is a need for improved methods of depositing a liner layer on a barrier layer, where the barrier layer is less metallic.

### SUMMARY

In an embodiment, the present disclosure generally provides a method of depositing a liner layer in a semiconductor structure. The method includes forming a passivation layer selectively on an exposed surface of a conductive layer within a via formed in a dielectric layer formed over the conductive layer, forming a barrier layer selectively on inner sidewalls of the via and a trench formed in the dielectric layer, forming the liner layer over the barrier layer on the inner sidewalls of the via and the trench, and filing a remaining portion of the via and the trench with a conductive material. Forming the liner layer includes holding a precursor gas in a gas line upstream from a processing chamber behind a closed programmable logic control (PLC) valve, wherein the precursor gas is held behind the closed PLC valve for a PLC valve close period and releasing the precursor gas into the processing chamber by opening the PLC valve, wherein the precursor gas is released into the processing chamber for a PLC valve open period.

In another embodiment, the present disclosure generally provides a method of selectively filling a via with a liner deposition in a semiconductor structure. The method includes forming a passivation layer selectively on an exposed surface of a conductive layer within the via formed in a dielectric layer formed over the conductive layer, forming a barrier layer selectively on inner sidewalls of the via, forming a liner layer over the barrier layer on the inner sidewalls of the semiconductor structure, and filling a remaining portion of the via and a trench with a third conductive material. The forming a liner layer further includes holding a precursor gas in a gas line upstream from a processing chamber behind a closed programmable logic control (PLC) valve, wherein the precursor gas is held behind the closed PLC valve for a PLC valve close period, the PLC valve close period is maintained until the pressure in the gas line is about 500 T and releasing the precursor gas into the processing chamber by opening the PLC valve, wherein the precursor gas is released into the processing chamber for a PLC valve open period; and

In another embodiment, the present disclosure generally provides a method of depositing a liner layer in a semiconductor structure. The method includes forming the liner layer over a barrier layer on inner sidewalls of the semiconductor structure, the liner layer comprising ruthenium (Ru). The forming of the liner layer includes holding a precursor gas in a gas line upstream from a processing chamber behind a closed programmable logic control (PLC) valve, wherein the precursor gas is held behind the closed PLC valve for a PLC valve close period, releasing the precursor gas into the processing chamber by opening the PLC valve, wherein the precursor gas is released into the processing chamber for a PLC valve open period, and sequentially repeating holding the precursor gas in the gas line upstream from the processing chamber behind the closed programmable logic control PLC valve and releasing the precursor gas into the processing chamber by opening the PLC valve.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to one or more embodiments.

FIG. 2 is a process flow diagram of a method of depositing a liner in a semiconductor structure, according to one or more embodiments.

FIGS. 3A, 3B, 3C, 3D, and 3E illustrate cross-sectional views of a portion of the interconnect structure corresponding to various operations of a method, according to one or more embodiments.

FIGS. 4A and 4B illustrate the pressure comparison between the method described herein and a best known method.

FIG. 5 is a plot illustrating ruthenium thickness with respect to the deposition time.

FIG. 6 is a plot illustration ruthenium thickness with respect to the deposition time.

FIG. 7 is a table illustrating trial examples of the pulsed chemical vapor deposition with programmable logic control.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to semiconductor device fabrication. More specifically, embodiments of the present disclosure relate to methods of forming a conformal liner on inner sidewalls of a via and a trench structure. Methods for depositing a ruthenium (Ru) liner via a pulsed chemical vapor deposition (CVD) with a programmable logic control (PLC) are provided herein. The pulsed CVD method is a method where the PLC controls the opening and closing of a PLC valve. When the PLC valve is closed, pressure increases in the gas lines upstream from the processing chamber because process gas (Ru) is held in the gas lines. The PLC valve closed period “charges” the process gas in the gas lines as the pressure increases. When the PLC valve is open, pressure decreases as the process gas exits the gas lines and enters the processing chamber. The increased pressure during the PLC valve closed period allows for the process gas to “burst” into the processing chamber during the PLC valve open period, which increases the concentration of process gas in the chamber during deposition. Depositing the Ru liner with a pulsed CVD method using PLC allows for the Ru liner to be deposited over a less metallic substrate (e.g., an untreated barrier layer) with a fast nucleation and a high continuity. This reduces the likelihood of particles to be deposited into the via and reduces the likelihood of degradation of the Ru liner. The pulsed CVD using PLC method allows for the following copper (Cu) gapfill process to be less challenging.

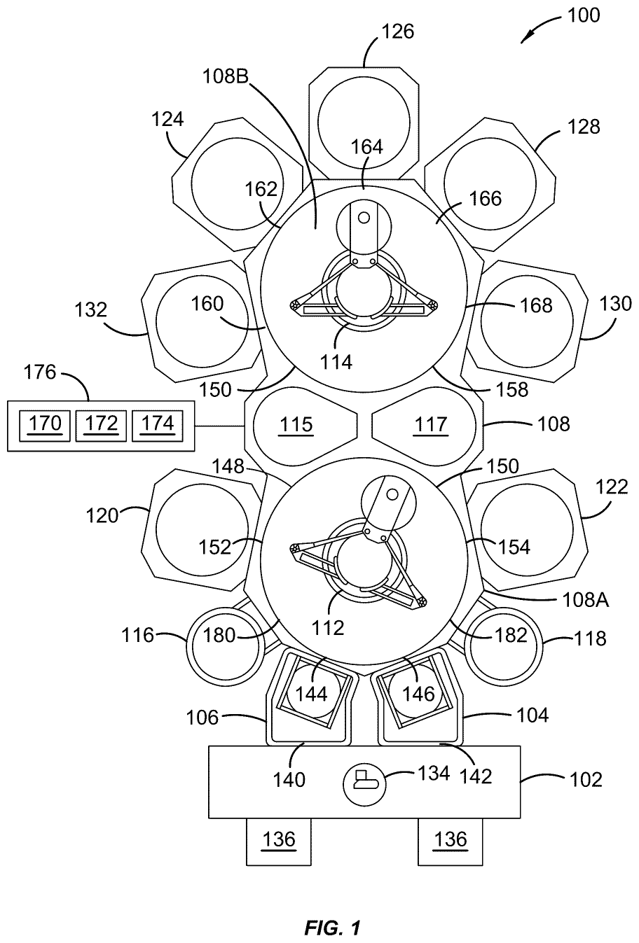

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of a middle-of-line (MOL) or back-end-of-line (BEOL) electrical connection during a chemical mechanical polishing (CMP) process. The multi-chamber processing system 100 generally includes a factory interface 102, load lock chambers 104, 106, a transfer chamber 108 (with a first portion 108A and a second portion 108B) with respective transfer robots 112, 114, holding chambers 115, 117, one or more optional service chambers 116, 118, and processing chambers 120, 122, 124, 126, 128, 130, 132. In one or more embodiments, the first portion 108A of the transfer chamber 108 and the second portion 108B of the transfer chamber 108 are separate transfer chambers. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura® Producer®, or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station and at least one factory interface robot 134 to facilitate transfer of substrates. The docking station is adapted to accept one or more front opening unified pods (FOUPs) 136. In some examples, each factory interface robot 134 generally includes a blade disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The first portion 108A of the transfer chamber 108 further has respective ports 148, 150 coupled to the holding chambers 115, 117, respective ports 180,182 coupled to one or more optional service chambers 116, 118, and respective ports 152, 154 coupled to processing chambers 120, 122. Similarly, the second portion 108B of the transfer chamber 108 has respective ports 156, 158 coupled to the holding chambers 115, 117 and respective ports 160, 162, 164, 166 coupled to processing chambers 124, 126, 128, 130, 132. The ports 144, 146, 148, 150, 152, 154, 156, 158, 160, 162, 164, 166, 180, 182 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chamber 108, the holding chambers 115, 117, one or more optional service chambers 116, 118, and the processing chambers 120, 122, 124, 126, 128, 130, 132 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134 transfers a substrate from the FOUP 136 through the port 140 or 142 to the load lock chamber 104 or 106. The gas and pressure control system then pumps down the load lock chamber 104 or 106. The gas and pressure control system further maintains the transfer chamber 108 and the holding chambers 115, 117 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108. In some embodiments, one or more optional service chambers (shown as 116 and 118) may be coupled to the transfer chamber 108. The service chambers 116 and 118 may be configured to perform other substrate processes, such as degassing, orientation, substrate metrology, cool down, and the like.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing, the one or more optional service chambers 116, 118 through the respective ports 180, 182, and the holding chambers 115, 117 through the respective ports 148, 150 for holding to await further transfer. Similarly, the transfer robot 114 is capable of accessing the substrate in the holding chamber 115 or 117 through the port 156 or 158 and is capable of transferring the substrate to and/or between any of the processing chambers 124, 126, 128, 130, 132 through the respective ports 160, 162, 164, 166, 168 for processing and the holding chambers 115, 117 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130, 132 can be any appropriate chamber for processing a substrate. In some examples, the processing chamber 120 can be capable of performing an etch process, the processing chamber 122 can be capable of performing a cleaning process, and the processing chambers 126, 128, 130, 132 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 124, 126, 128, 130, or 132 may be a Volta™ CVD/ALD chamber, Trillium™ ALD chamber, or Encore™ PVD chambers available from Applied Materials of Santa Clara, Calif.

A system controller 176 is coupled to the multi-chamber processing system 100 for controlling the multi-chamber processing system 100 or components thereof. For example, the system controller 176 may control the operation of the multi-chamber processing system 100 using a direct control of the chambers 104, 106, 108, 115, 116, 117, 118, 120, 122, 124, 126, 128, 130, 132 of the multi-chamber processing system 100 or by controlling controllers associated with the chambers 104, 106, 108, 115, 116, 117, 118, 120, 122, 124, 126, 128, 130, 132. In operation, the system controller 176 enables data collection and feedback from the respective chambers to coordinate performance of the multi-chamber processing system 100.

The system controller 176 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 176 is configured to perform methods such as the method 200 stored in the memory 172.

Other processing systems can be in other configurations. For example, more or fewer processing chambers may be coupled to a transfer apparatus. In the illustrated example, the transfer apparatus includes the transfer chambers 108 and the holding chambers 115, 117. In other examples, more or fewer transfer chambers (e.g., one transfer chamber) and/or more or fewer holding chambers (e.g., no holding chambers) may be implemented as a transfer apparatus in a processing system.

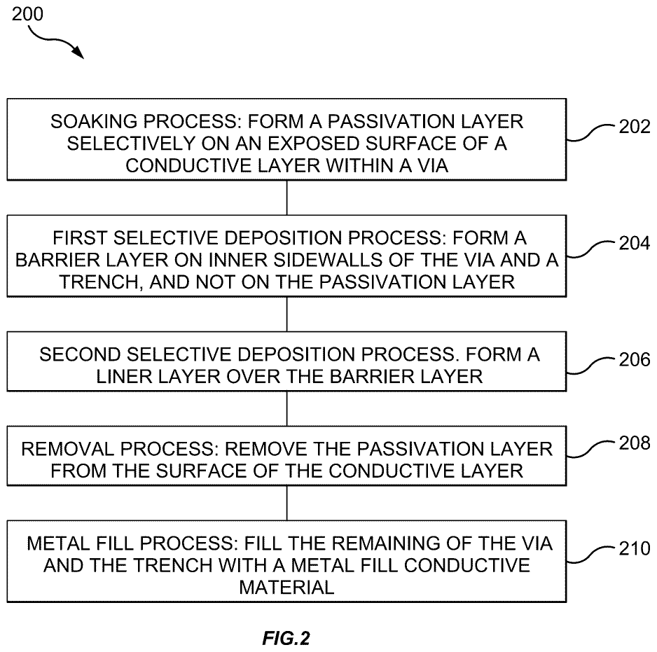

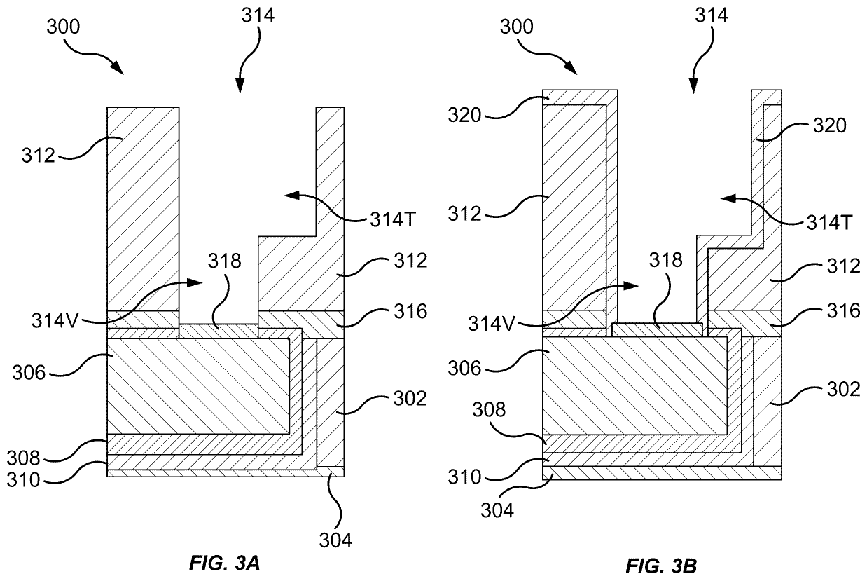

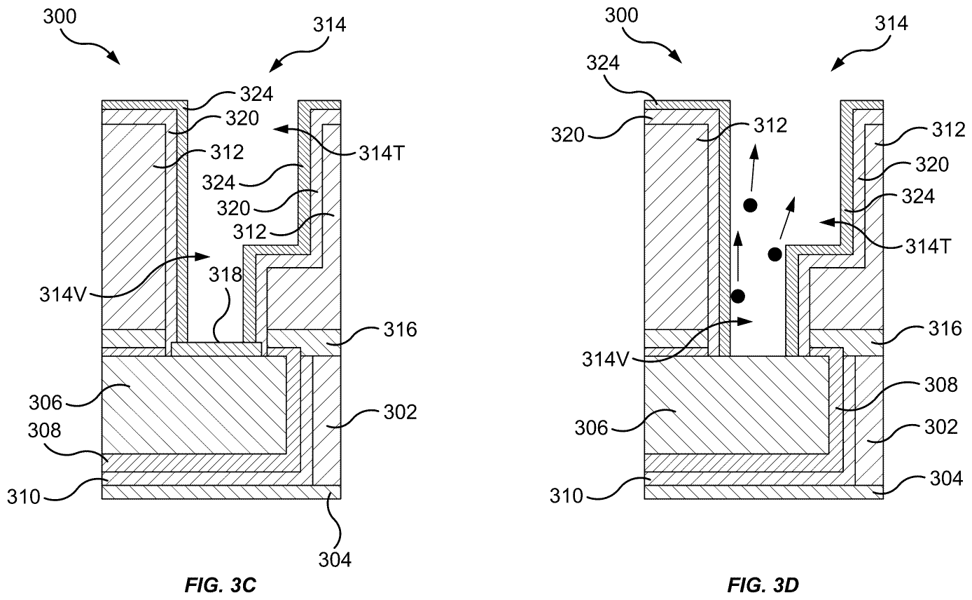

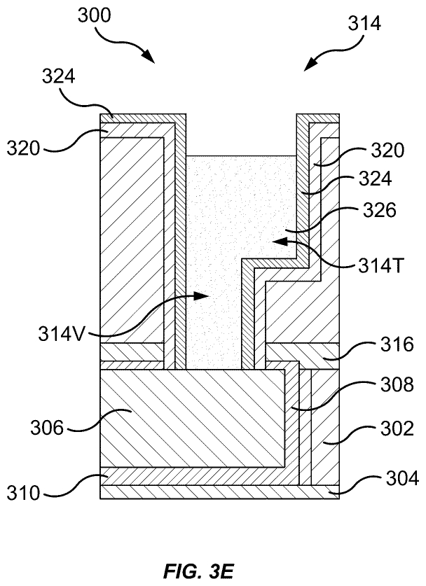

FIG. 2 is a process flow diagram of a method 200 of depositing a liner layer 324 in a semiconductor structure, according to one or more embodiments. FIGS. 3A-3E are cross-section views of a portion of the interconnect structure 300 corresponding to the various operations of the method 200. It should be understood that FIG. 3A-3E illustrate cross-sectional views of a portion of the interconnect structure 300 formed on a substrate. FIGS. 3A-3E are only partial schematic views of the interconnect structure 300, and the interconnect structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

As shown in FIGS. 3A-3E, particularly in FIG. 3A, the interconnect structure 300 includes a first dielectric layer 302 formed on a substrate (not shown). The first dielectric layer 302 may be formed of a dielectric material, such as low k dielectric (SiCOH), silicon dioxide (SiO₂), silicon nitride (Si₃N₄), silicon carbide (SiC), aluminum oxide (Al₂O₃), or aluminum nitride (AlN). A first etch stop layer 304 may be disposed between the first dielectric layer 302 and the substrate. The interconnect structure 300 further includes a conductive layer 306 embedded within the first dielectric layer 302 and separated from the first dielectric layer 302 by a liner layer 308 and a barrier layer 310. The conductive layer 306 may be formed of copper (Cu), cobalt (Co), molybdenum (Mo), tungsten (W), or ruthenium (Ru). The liner layer 308 may be formed of ruthenium (Ru) and cobalt (Co), or RuCo. The barrier layer 310 may be formed of tantalum nitride (TaN) or doped tantalum nitride (TaN). The interconnect structure 300 further includes a second dielectric layer 312, having one or more features 314, such as a via 314V and a trench 314T formed therein, over the first dielectric layer 302 and the conductive layer 306. The second dielectric layer 312 may be formed of the same material as the first dielectric layer 302, such as low k dielectric (SiCOH), silicon dioxide (SiO₂), silicon nitride (Si₃N₄), silicon carbide (SiC), aluminum oxide (Al₂O₃), or aluminum nitride (AlN). In another embodiment, the second dielectric layer 312 may be formed of a different material from the first dielectric layer 302, while maintaining the same low-k properties. A second etch stop layer 316 may be disposed between the second dielectric layer 312 and the first dielectric layer 302. Within the via 314V, a surface of the conductive layer 306 is exposed.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

At operation 202, a soaking process is performed to form a passivation layer 318 selectively on the exposed surface of the conductive layer 306 within the via 314V, as shown in FIG. 3A. The soaking process may be formed in a processing chamber, such as processing chamber 124, 126, 128, 130, or 132 shown in FIG. 1.

The passivation layer 318 may be formed of a self-assembled monolayer (SAM) of organic molecules. In the soaking process, the interconnect structure 300 is soaked in a gas precursor including an unsaturated hydrocarbon, at a temperature of less than about 450° C. and a pressure of less than about 80 Torr for a time duration of greater than about 10 seconds, with a flow rate of the precursor of between 50 sccm and about 600 sccm. In some embodiments, a liquid precursor is used in the soaking process. In the soaking process, organic molecules in the precursor are absorbed only on a metal surface, such as the exposed surface of the conductive layer 306. The passivation layer 318 may act as a block layer that suppresses nucleation or growth of a subsequent material deposition thereon.

At operation 204, a first selective deposition process is performed to form a barrier layer 320 on inner sidewalls of the via 314V and the trench 314T, and not on the passivation layer 318, as shown in FIG. 3B. The first selective deposition process may include an atomic layer deposition (ALD) process in a processing chamber, such as the processing chamber 124, 126, 128, 130, or 132 shown in FIG. 1.

The barrier layer 320 may be formed of tantalum nitride (TaN) or doped tantalum nitride (TaN), metal doped TaN, titanium nitride (TiN), tungsten nitride (WN), or tungsten nitride carbide (WCN). The selectivity in the first selective deposition process may arise from differences in nucleation of the barrier layer 320 on exposed surfaces of the second dielectric layer 312 (e.g., silicon dioxide (SiO₂) or silicon nitride (Si₃N₄)) and on the passivation layer 318. In some embodiments, the barrier layer 320 is deposited by sequentially exposing the interconnect structure 300 to a metal precursor and a reactant.

At operation 206, the liner layer 324 is selectively deposited by a pulsed CVD method on the barrier layer 320 on the inner sidewalls of the via 314V and the trench 314T, as shown in FIG. 3C. The liner layer 324 may be formed of a conductive material such as ruthenium (Ru), cobalt (Co), molybdenum (Mo), or tungsten (W). The liner layer 324 is deposited with a pulsed CVD method that includes programmable logic control (PLC). The pulsed CVD method is a method where the PLC controls the opening and closing of a PLC valve. When the PLC valve is closed, pressure increases in the gas lines upstream from the processing chamber because process gas (e.g., Ru) is held in the gas lines. The PLC valve close period “charges” the process gas in the gas lines as the pressure increases. In one or more embodiments, the PLC valve close period is about 1 seconds to about 100 seconds. When the PLC valve is open, pressure decreases as the process gas exits the gas lines and enters the processing chamber. The increased pressure during the PLC valve closed period allows for the process gas to “burst” into the processing chamber during the PLC valve open period, which increases the concentration of process gas in the process chamber during deposition. In one or more embodiments, the PLC valve open period is about 1 seconds to about 100 seconds. In one or more embodiments, the PLC valve open period and the PLC valve close period is dependent on a transducer pressure and a carrier flow rate. For example, if the carrier gas flow rate is slow (e.g., less than 300 sccm), the PLC valve close period is longer such that the process gas “charges” in the gas lines. In one or more embodiments, the process gas “charges” in the gas lines (e.g., during the PLC valve close period) until a pressure of about 500 T is reached. In one or more embodiments, the PLC valve close period and the PLC valve open period is repeated until the desired thickness of the film is achieved.

The liner layer 324 may be deposited in a processing chamber, such as the processing chamber 124, 126, 128, 130, or 132 in FIG. 1. The PLC is used to control the PLC valve located between the gas lines and the processing chamber (e.g., processing chamber 124, 126, 128, 130, or 132). The pulsed CVD method continues until the liner layer 324 reaches the required thickness. For example, the pulsed CVD method of Operation 206 is repeated at least five times.

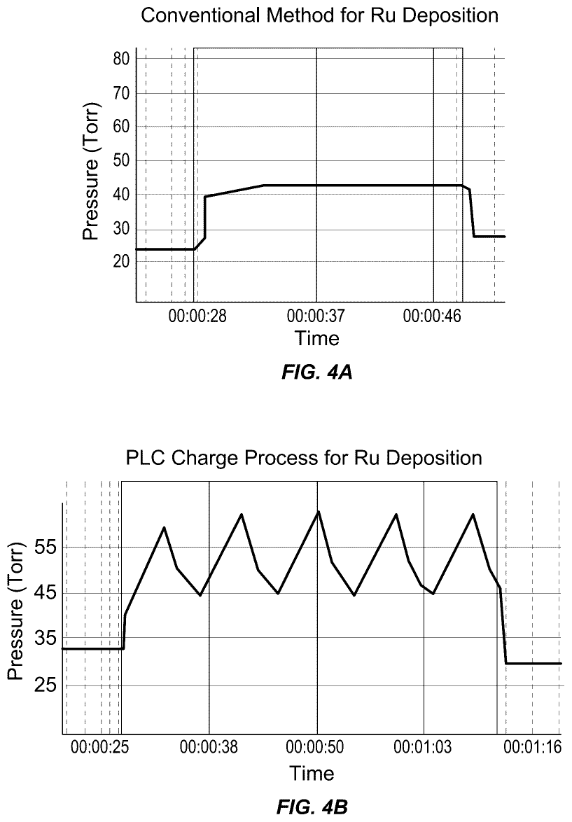

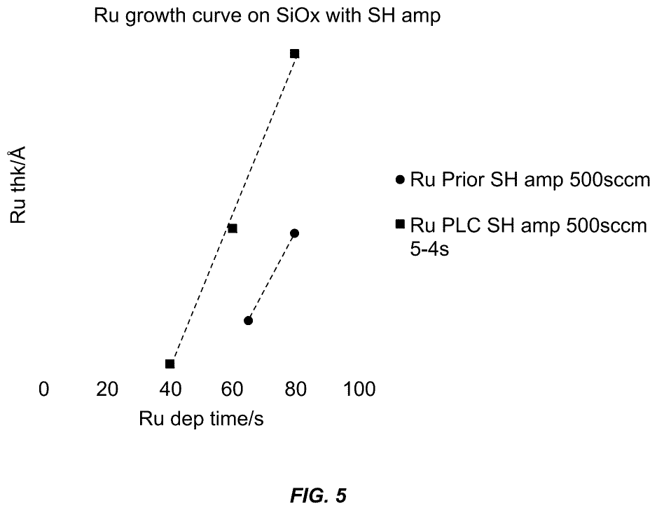

As shown in FIG. 4A, typical Ru deposition by prior methods include a constant pressure as the Ru precursor is released into the processing chamber (e.g., processing chamber 124, 126, 128, 130, or 132). In the present disclosure, Ru deposition is performed through a pulsed CVD method using PLC. During this method, there is a PLC valve close period, which allows pressure to build in the lines holding Ru precursor in the multi-chamber processing system 100 (e.g. during the PLC valve close period, the Ru precursor “charges” within the gas line upstream from the processing chamber). There is a PLC valve open period, which allows the Ru precursor to enter the processing chamber (e.g., processing chamber 124, 126, 128, 130, or 132), which causes the pressure in the multi-chamber processing system 100 to decrease. As shown in FIG. 4B, the PLC valve close period is represented by increased pressure and PLC valve open period is represented by decreased pressure in the multi-chamber processing system 100. Further, as shown in 4B, operation 206 includes multiple cycles of the PLC valve close period and the PLC valve open period. In one or more embodiments, the multiple cycles continue until a liner layer 324 target thickness is achieved. The pulsed CVD method allows for an increased concentration of Ru precursor to enter the processing chamber due to the increase in pressure in the gas line upstream from the processing chamber during the PLC valve close period. The increased pressure in the gas line upstream from the processing chamber results in a “burst” of Ru precursor to enter the processing chamber (e.g., processing chamber 124, 126, 128, 130, or 132) during the PLC valve open period.

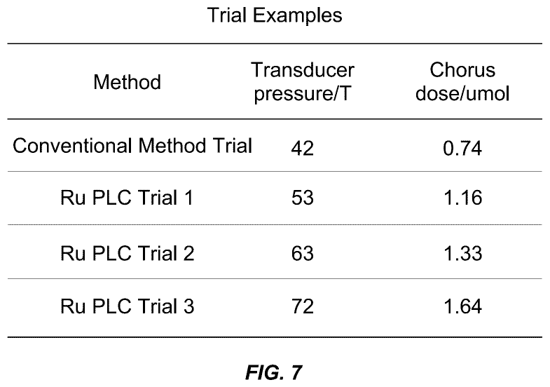

As shown in FIG. 7, trial examples of the pulsed CVD method using PLC are described compared to a conventional method trial. All the trials included Ru precursor entering the processing chamber (e.g., processing chamber 124, 126, 128, 130, or 132) for twenty seconds. The transducer pressure is the pressure in the gas line upstream from the ampule and the processing chamber (e.g., processing chamber 124, 126, 128, 130, or 132). The concentration (chorus dose/umol) of Ru is measured in the gas lines upstream from the point the Ru precursor enters the processing chamber (e.g., processing chamber 124, 126, 128, 130, or 132). The conventional method trial includes a method where Ru precursor was flowed into the processing chamber (e.g., processing chamber 124, 126, 128, 130, or 132) for 20 seconds where the transducer pressure/T was 42. The conventional method trial includes a 0.74 chorus dose/umol concentration of Ru in the lines before the Ru precursor enters the processing chamber. The Ru PLC Trial 1 includes a method where the PLC valve close period was 3 seconds and the PLC valve open period was 4 seconds for the cycle. The cycle was repeated 5 times. The transducer pressure/T was 53. Ru PLC Trial 1 includes a 1.15 chorus dose/umol concentration of Ru in the lines before the Ru precursor enters the processing chamber. The Ru PLC Trial 2 includes a method where the PLC valve close period was 5 seconds and the PLC valve open period was 4 seconds for the cycle. The cycle was repeated 5 times. The transducer pressure/T was 63. Ru PLC Trial 2 includes a 1.33 chorus dose/umol concentration of Ru in the lines before the Ru precursor enters the processing chamber. Ru PLC Trial 3 includes a method where the PLC valve close period was 7 seconds and the PLC valve open period was 4 seconds for the cycle. The cycle was repeated 5 times. The transducer pressure/T was 72. Ru PLC Trial 3 includes a 1.64 chorus dose/umol concentration of Ru in the lines before the Ru precursor enters the processing chamber. The Ru PLC trials indicate that the “charge,” during the PLC valve close period, allows for an increased concentration of Ru to enter the processing system during the “burst,” during the PLC valve open period, due to the increased chorus dose/umol of Ru in the gas lines of the multi-chamber processing system 100. For example, as shown in FIG. 7, the concentration of Ru precursor delivery is more than 2 times greater using a pulsed CVD method in Trial 3 when compared to Ru precursor delivery with a conventional method process. It should be understood that the trials are examples of parameters available for a pulsed CVD method. In one or more examples, the cycle of the PLC valve close period and PLC valve open period may be repeated any number of times. In one or more examples, the time allotted for the PLC valve open period or PLC valve close period may be any amount of time.

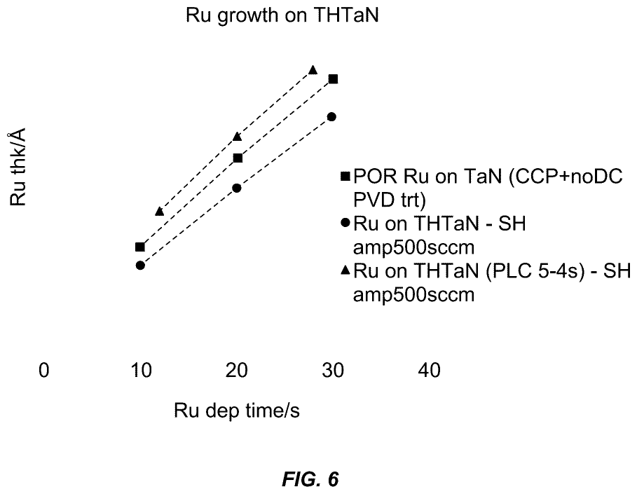

The deposition of the liner layer 324 by the pulsed CVD method with PLC allows for fewer particle issues during liner layer 324 growth, reduced Ru precursor degradation, faster Ru precursor nucleation, and higher Ru film continuity and quality. The pulsed CVD method allows for time during the PLC valve close period to remove impurities from the deposited film. The pulsed CVD method allows for a reduced volume of carrier gas flow into the processing chamber (e.g., processing chamber 124, 126, 128, 130, or 132), which reduces the precursor agitation resulting in particles. For example, as shown in FIG. 5, when depositing on SiOx, Ru precursor nucleation during the pulsed CVD method occurs about 16 seconds earlier than the Ru precursor nucleation during the conventional method deposition process (e.g., there is no nucleation delay during the pulsed CVD method). For example, as shown in FIG. 6, the deposition rate of Ru using the pulsed CVD method (Ru on TaN (PLC 5-4s)) is increased when compared to the conventional method examples (Ru on THTaN-SH amp500 sccm and POR Ru on THTaN (CCP+noDC PCD trt)).

At operation 208, a removal process is performed to remove the passivation layer 318 from the surface of the conductive layer 306, as shown in FIG. 3D. The removal process may include a dry etch process in an etch chamber, such as the processing chamber 122 shown in FIG. 1.

The removal process may include an anisotropic remote plasma assisted dry etch process, such as a reactive ion etching (RIE) process, using a plasma formed from a gas including argon (Ar), helium (He), nitrogen (N₂), hydrogen (H₂), ammonia (NH₃), or a combination thereof. The plasma effluents directionally bombard and remove the passivation layer 318.

At operation 210, a post treatment process occurs. In one or more embodiments, a metal fill process is performed to fill the remaining of the via 314V and the trench 314T with a metal fill conductive material 326, as shown in FIG. 3F. The metal fill conductive material 326 may be copper (Cu), cobalt (Co), ruthenium (Ru), or molybdenum (Mo). The metal fill process may include a chemical vapor deposition (CVD) process, a physical vapor deposition (PVD), and an electro plating process, in a processing chamber, such as the processing chamber 124, 126, 128, 130 or 132 shown in FIG. 1.

Embodiments described herein generally relate to semiconductor device fabrication. More specifically, embodiments of the present disclosure relate to methods of forming a conformal liner on inner sidewalls of a via and a trench structure. Methods for depositing a ruthenium (Ru) liner via a pulsed chemical vapor deposition (CVD) with a programmable logic control (PLC) are provided herein. Depositing the Ru liner with a pulsed CVD method using PLC allows for the Ru liner to be deposited over a less metallic substrate (e.g., an untreated barrier layer) with a fast nucleation and a high continuity. This reduces the likelihood of particles to be deposited into the via and reduces the likelihood of degradation of the Ru liner. The pulsed CVD using PLC method allows for the following copper (Cu) gapfill process to be less challenging.

While the foregoing is directed to embodiments of the present disclosure, other and further embodiments of the disclosure may be devised without departing from the basic scope thereof, and the scope thereof is determined by the claims that follow.

1. A method of depositing a liner layer in a semiconductor structure, comprising:
forming a passivation layer selectively on an exposed surface of a conductive layer within a via formed in a dielectric layer formed over the conductive layer;
forming a barrier layer selectively on inner sidewalls of the via and a trench formed in the dielectric layer;
forming the liner layer over the barrier layer on the inner sidewalls of the via and the trench, forming the liner layer comprising:
holding a precursor gas in a gas line upstream from a processing chamber behind a closed programmable logic control (PLC) valve, wherein the precursor gas is held behind the closed PLC valve for a PLC valve close period; and
releasing the precursor gas into the processing chamber by opening the PLC valve, wherein the precursor gas is released into the processing chamber for a PLC valve open period; and
filling a remaining portion of the via and the trench with a conductive material.

2. The method of claim 1, further comprising:
removing the passivation layer from a surface of the conductive layer, subsequent to the forming of the barrier layer and the liner layer.

3. The method of claim 1, wherein holding the precursor gas in the gas line upstream from the processing chamber behind the closed PLC valve and releasing the precursor gas into the processing chamber by opening the PLC valve is sequentially repeated.

4. The method of claim 3, wherein holding the precursor gas in the gas line upstream from the processing chamber behind the closed PLC valve and releasing the precursor gas into the processing chamber by opening the PLC valve is sequentially repeated until a desired film thickness if formed.

5. The method of claim 1, wherein the passivation layer comprises a self-assembled monolayer (SAM) of organic molecules.

6. The method of claim 1, wherein the dielectric layer comprises low k dielectric (SiOCH), silicon dioxide (SiO₂), silicon nitride (Si₃N₄), silicon carbide (SiC), aluminum oxide (Al₂O₃), or aluminum nitride (AlN).

7. The method of claim 1, wherein the barrier layer comprises tantalum nitride (TaN), metal doped TaN, titanium nitride (TiN), tungsten nitride (WN), or tungsten nitride carbide (WCN).

8. The method of claim 1, wherein the liner layer comprises ruthenium (Ru).

9. The method of claim 1, wherein the PLC valve close period is maintained until a pressure of about 500 T is reached in the gas line.

10. A method of selectively filling a via with a liner deposition in a semiconductor structure, comprising:
forming a passivation layer selectively on an exposed surface of a conductive layer within the via formed in a dielectric layer formed over the conductive layer;
forming a barrier layer selectively on inner sidewalls of the via;
forming a liner layer over the barrier layer on the inner sidewalls of the semiconductor structure, the liner layer comprising ruthenium, forming the liner layer further comprises:
holding a precursor gas in a gas line upstream from a processing chamber behind a closed programmable logic control (PLC) valve, wherein the precursor gas is held behind the closed PLC valve for a PLC valve close period, the PLC valve close period is maintained until a pressure in the gas line is about 500 T; and
releasing the precursor gas into the processing chamber by opening the PLC valve, wherein the precursor gas is released into the processing chamber for a PLC valve open period; and
filling a remaining portion of the via and a trench with a conductive material.

11. The method of claim 10, further comprising:
removing the passivation layer from a surface of the conductive layer, subsequent to the forming of the barrier layer and the liner layer.

12. The method of claim 10, wherein holding the precursor gas in the gas line upstream from the processing chamber increases the pressure in the gas line of a processing system.

13. The method of claim 10, wherein holding the precursor gas in the gas line upstream from the processing chamber increases a concentration of the precursor gas in the gas line of a processing system.

14. The method of claim 10, the PLC valve close period and the PLC valve open period are different values.

15. The method of claim 10, wherein the dielectric layer comprises low k dielectric (SiCOH), silicon dioxide (SiO₂), silicon nitride (Si₃N₄), silicon carbide (SiC), aluminum oxide (Al₂O₃), or aluminum nitride (AlN).

16. The method of claim 10, wherein the barrier layer comprises tantalum nitride (TaN), metal doped TaN, titanium nitride (TIN), tungsten nitride (WN), or tungsten nitride carbide (WCN).

17. A method of depositing a liner layer in a semiconductor structure, comprising:
forming the liner layer over a barrier layer on inner sidewalls of the semiconductor structure, the liner layer comprising ruthenium (Ru), forming the liner layer comprising:
holding a precursor gas in a gas line upstream from a processing chamber behind a closed programmable logic control (PLC) valve, wherein the precursor gas is held behind the closed PLC valve for a PLC valve close period;
releasing the precursor gas into the processing chamber by opening the PLC valve, wherein the precursor gas is released into the processing chamber for a PLC valve open period; and
sequentially repeating holding the precursor gas in the gas line upstream from the processing chamber behind the closed programmable logic control PLC valve and releasing the precursor gas into the processing chamber by opening the PLC valve.

18. The method of claim 17, wherein the method is sequentially repeated five times.

19. The method of claim 17, the PLC valve close period and the PLC valve open period are different values.

20. The method of claim 17, wherein the PLC valve close period is maintained until a pressure of about 500 T is reached in the gas line.
